(19) United States
(12) Patent Application Publication
(10) Pub. No.: US 2008/0157065 A1
(43) Pub. Date: Jul. 3, 2008

(54) Compositions, layers and films for optoelectronic devices, methods of production and uses thereof

(76) Inventors: Ahila Krishnamoorthy, Chennai (IN); Joseph Kennedy, San Jose, CA (US); Richard Spear, Santa Cruz, CA (US); Deborah Yellowaga, Chandler, AZ (US); Peter Smith, Long Valley, NJ (US); Ben Palmer, Phoenix, AZ (US); Ronald Katsanes, Newark, CA (US); Michael Tucker, Tempe, AZ (US)

Correspondence Address: BUCHALTER NEMER, 18400 VON KARMAN AVE., SUITE 800, IRVINE, CA, 92612, US

(21) Appl. No.: 11/784,966

(22) Filed: Apr. 10, 2007

Related U.S. Application Data
(63) Continuation-in-part of application No. 11/192,352, filed on Jul. 29, 2005.
Application No. 11/192,352 is a continuation-in-part of application No. 10/910,673, filed on Aug. 3, 2004, now Pat. No. 7,015,061.

(51) Int. Cl. H01L 51/50; H01L 33/00; C08G 77/04; B32B 27/00; B32B 9/00

(52) U.S. Cl. 257/40; 438/22; 525/478; 428/409; 428/446; 525/477; 257/E51.001; 257/E33.001

(57) ABSTRACT

Optoelectronic devices are described that include: a) a surface within the device, and b) at least one sufficiently light-transmissive crosslinked film, wherein the film is formed from at least one silicon-based material, at least one catalyst, and at least one solvent. Optoelectronic device are also disclosed, which include: a) a surface within the device, and b) at least one light-transmissive crosslinkable composition, wherein the composition comprises at least one silicon-based material, at least one crosslinking agent and at least one solvent. Methods of producing optoelectronic devices are also disclosed that include: a) providing a surface, b) providing at least one sufficiently light-transmissive crosslinkable composition, wherein the composition comprises at least one silicon-based material and at least one catalyst, c) applying the crosslinkable material to the surface, and d) curing the crosslinkable material to form a sufficiently light-transmissive crosslinked composition. Crosslinkable compositions are disclosed that comprise: polyphenylsilsesquioxane, polyphenylsiloxane or a combination thereof, tetramethylammonium nitrate, at least one solvent, and an aminopropyl triethoxysilane-based compound.

This application is a continuation-in-part of US Published Application 2006/0035419, U.S. Ser. No. 11/192,352 filed on Jul. 29, 2005, which is a continuation-in-part of U.S. Issued Pat. No. 7,015,061, which was filed on Aug. 3, 2004 and issued on Mar. 21, 2006. Both of these applications are incorporated by reference in their entirety.

### STATEMENT OF GOVERNMENT LICENSE RIGHTS

The U.S. Government has a paid-up license in this invention and the right in limited circumstances to require the patent owner to license others on reasonable terms as provided for by the terms of MDA972-93-2-0014, Article VIII, B.1 awarded by the Army Research Laboratory (ARL) to the United States Display Consortium.

### FIELD OF THE SUBJECT MATTER

The field of the subject matter is compositions and films made from those compositions that are utilized in optoelectronic devices and applications. Methods of production of the compositions and films are also disclosed, along with methods of using same in the production of the optoelectronic devices and applications.

### BACKGROUND

The production of display devices, such as electrooptic elements and thin film transistors, is known from U.S. Pat. No. 6,674,106, which is incorporated herein by reference. One of the challenges of producing optoelectronic and microelectronic devices and using them in various applications is the production of materials that can be utilized to serve several different functions, such as dielectric coatings, planarization films and layers, passivation layers, color filter planarizing overcoats for Liquid Crystal Displays (LCDs) and/or other displays, Organic Light-Emitting Diodes (OLED) moisture barrier coatings and adhesives, films and layers in flat panel displays and transistors.

U.S. Pat. No. 6,177,360 issued to Carter et al. (“Carter”) discloses a process for making an integrated circuit device that comprises a substrate, a series of metallic circuit lines and a dielectric material positioned on the circuit lines. Although the dielectric material comprises the condensation product of silsesquioxane in the presence of a photosensitive or thermally sensitive base generator, it is not disclosed that this dielectric material can crossover into optoelectronic applications. It is also not clear from Carter that the dielectric materials contemplated should be transparent or light transmissive. Further, there is nothing in Carter to indicate that the dielectric materials can be modified with surfactants, crosslinking agents or adhesion promoters, which would be useful when working with a number of different types of materials, layers and substrates, as are often present in optoelectronic applications. Also, Carter is silent concerning characteristics relevant to some of the end uses herein, such as planarization, surface roughness or index of refraction and other end uses, such as those described herein.

To this end, it would be desirable to form and utilize a light transmissive composition that can satisfy one or more of the following: a) serve several different functions, including as a passivation layer, a color filters coating, an OLED moisture barrier coating and adhesive, and a film and/or layer in flat panel displays and transistors; b) adequately gap fill in narrow trenches and channels; c) be formed using conventional structural and solvent constituents; d) withstand incorporation of other composition-modifying constituents, such as surfactants, crosslinking agents, additives and adhesion promoters; and/or e) planarize a surface or substrate to form a component that can be easily incorporated into an optoelectronic application.

### SUMMARY OF THE SUBJECT MATTER

Optoelectronic devices are described that include: a) a surface within the device, and b) at least one sufficiently light-transmissive crosslinked film, wherein the film is formed from at least one silicon-based material, at least one catalyst, and at least one solvent.

Optoelectronic device are also disclosed, which include: a) a surface within the device, and b) at least one light-transmissive crosslinkable composition, wherein the composition comprises at least one silicon-based material, at least one crosslinking agent and at least one solvent.

Methods of producing optoelectronic devices are also disclosed that include: a) providing a surface, b) providing at least one sufficiently light-transmissive crosslinkable composition, wherein the composition comprises at least one silicon-based material and at least one catalyst, c) applying the crosslinkable material to the surface, and d) curing the crosslinkable material to form a sufficiently light-transmissive crosslinked composition.

Crosslinkable compositions are disclosed that comprise: polyphenylsilsesquioxane, polyphenylsiloxane or a combination thereof, tetramethylammonium nitrate, at least one solvent, and an aminopropyl triethoxysilane-based compound.

### BRIEF DESCRIPTION OF THE FIGURES

FIG. 1(a) shows a cross-section of a thin film transistor (100) comprising a substrate (110), a surface (120) with topography and a conformal layer or coating comprising SiNₓ applied by chemical vapor deposition (CVD).

FIG. 1(b) shows a cross-section of a thin film transistor (105) comprising a substrate (110) and a surface (120) with topography and a planarizing layer (140).

FIG. 2 shows the cross section of a typical thin film transistor device (200) in which a contemplated formulation is used as a gate dielectric (230).

FIG. 3 shows a contemplated device (300) where the surface is planarized using the contemplated formulation (320).

FIG. 4(a) shows the cross-section of a typical color filter.

FIG. 4(b) shows how contemplated materials are used in a color filter.

FIG. 5 shows the cross section of an active matrix organic light emitting diode (AMOLED) (500).

FIG. 6 shows a schematic cross-sections of a contemplated LED (601) and the breakout of a contemplated LED (600), wherein the compositions contemplated herein may be utilized on top of the LED in top-emitting LEDs or on the substrate at the bottom for the bottom emitting LEDs (not shown).

FIGS. 7(a) and 7(b) show contemplated flexible substrates. These substrates (710) are in general rough (roughness of the order of a few hundred nanometers) as shown in the figure.

FIG. 8 shows a typical cross section of a solar cell (800).

FIG. 9 shows an X-ray detector (900), which comprises a sensor (photoconductor), capacitor and an active matrix thin film transistor addressing unit.

FIG. 10 shows a typical post-bake spin curve for Example 4.

FIG. 11 shows a contemplated curing profile for a 300° C. cure.

FIGS. 12 and 13 show respectively the weight loss of 230° C. and 300° C. cured material.

Table 1 shows the cumulative weight loss after ramp and after 1, 2 and 3 hours of holding at a cure temperature.

FIG. 14 shows a schematic depiction of a micrograph, where the surface is planarized by the contemplated material.

FIG. 15 shows a cross-section of the organic TFT (OTFT) (1500) fabricated to test the contemplated material as gate dielectric.

Table 2 shows the annealing conditions for the semiconductor of Example 5.

FIGS. 16(a) and (b) show the device characteristics of OTFT.

### DETAILED DESCRIPTION

In optical applications, organic materials that are being used as a part of the device are often unstable at higher temperature, are colored and have lower light transmittance (less than about 95%). Thus, there exists a need in the art for materials that are stable at high temperatures and provide crack-free and void-free gap-fill of narrow features at low process temperatures. It may also be useful in some cases for such materials to have adequate mechanical and chemical strength to withstand subtractive processes, such as enhanced O₂ plasma and wet etch processes.

Surprisingly, useful compositions have been developed and utilized in such a manner that can satisfy one or more of the following: a) serve several different functions, including as a passivation layer, a color filter planarizing overcoat, an OLED moisture barrier coating and adhesive, and a film and/or layer in flat panel displays and transistors; b) adequately gap fill in narrow trenches and channels; c) be formed using conventional structural and solvent constituents; d) withstand incorporation of other composition-modifying constituents, such as surfactants and adhesion promoters; and/or e) planarize a surface or substrate to form a component that can be easily incorporated into an optoelectronic application. To date, there has been no appreciation in the art that the compositions, films and layers described herein can be used in the manner described herein.

Contemplated crosslinkable compositions comprise at least one silicon-based compound, at least one catalyst, and at least one solvent. These compositions may also comprise at least one surfactant, at least one crosslinking agent, at least one adhesion promoter, at least one other additive or a combination thereof. Contemplated crosslinkable compositions are applied to suitable surfaces depending on the projected end-use of the coating, layer or film. The at least one catalyst is activated at a suitable point in the production of the layered material, device, film or display, thereby forming the light-transmissive film or layer.

Optoelectronic devices are also contemplated herein utilizing the above compositions to form a film, layer or coating as part of the device or apparatus. The optoelectronic device may comprise one or more light-transmissive films, coatings or layers, such as those described herein, and those light-transmissive films or layer may comprise the same chemical composition or one that is slightly different from another light-transmissive film or layer. In some embodiments, contemplated optoelectronic devices comprise a surface within the device, and at least one sufficiently light-transmissive crosslinked film, wherein the film is formed from at least one silicon-based material, at least one catalyst, and at least one solvent. Optoelectronic devices may also comprise a surface within the device, and at least one sufficiently light-transmissive crosslinkable composition, wherein the composition comprises at least one silicon-based material, at least one crosslinking agent and at least one solvent.

Contemplated optoelectronic devices comprise a transistor, a light-emitting diode, a color filter, a stainless steel or plastic surface, a photovoltaic cell, a flat panel display, x-ray detectors or a combination thereof. Contemplated devices comprise an active matrix thin film organic light emitting display, a passive matrix organic light emitting display, an active matrix thin film transistor liquid crystal display or a combination thereof. Contemplated transistors comprise an amorphous silicon thin film transistor, a low temperature polysilicon transistor, an organic transistor, an organic field effect transistor, a static induction transistor, a crystalline silicon transistor or a combination thereof. In some embodiments, the light-transmissive film forms a passivation layer, a planarization layer or a combination thereof.

### Crosslinkable Compositions

### Silicon-Based Compounds

It is important to first understand the components that make up the crosslinkable compositions contemplated herein. These compositions comprise at least one silicon-based compound. Examples of silicon-based compounds comprise siloxane, silsesquioxane, or silazane compounds, such as methylsiloxane, methylsilsesquioxane, phenylsiloxane, phenylsilsesquioxane, methylphenylsiloxane, methylphenylsilsesquioxane, silazane polymers, dimethylsiloxane, diphenylsiloxane, methylphenylsiloxane, polyphenylsilsesquioxane, polyphenylsiloxane, silicate polymers and combinations thereof. A contemplated silazane polymer is perhydrosilazane, which has a “transparent” polymer backbone. Contemplated compounds and materials are those that do not meaningfully absorb in the visible range, such as between 400 nm and 800 nm. In contemplated embodiments, the at least one silicon-based compound comprises polyphenylsilsesquioxane, polyphenylsiloxane or a combination thereof.

Some contemplated silicon-based compounds include compositions formed from hydrolysis-condensation reactions of at least one reactant having the formula:

R¹ₓSi(OR²)_{y},

where R¹ is an alkyl, alkenyl, aryl, or aralkyl group, and x is an integer between 0 and 2, and where R² is a alkyl group or acyl group and y is an integer between 0 and 2. Materials also contemplated include silsequioxane polymers of the general formula (C₆H₅SiO_{1.5})ₓ, where x is an integer greater than about 4.

Some contemplated silicon-based compounds include siloxane polymers, copolymers and blockpolymers, hydrogensiloxane polymers of the general formula (H_{0-1.0}SiO_{1.5-2.0})ₓ, hydrogensilsesquioxane polymers, which have the formula (HSiO_{1.5})ₓ, where x is greater than about four and derivatives of silicic acid and combinations thereof. Also included are copolymers of hydrogensilsesquioxane and an alkoxyhydridosiloxane or hydroxyhydridosiloxane. Materials contemplated herein additionally include organosiloxane polymers, acrylic siloxane polymers, silsesquioxane-based polymers, derivatives of silicic acid, organohydridosiloxane polymers of the general formula (H_{0-1.0}SiO_{1.5-2.0})ₙ(R_{0-1.0}SiO_{1.5-2.0})ₘ, and organohydridosilsesquioxane polymers of the general formula (HSiO_{1.5})ₙ(RSiO_{1.5})ₘ, where m is greater than zero and the sum of n and m is greater than about four and R is alkyl or aryl, and combinations thereof. Some useful organohydridosiloxane polymers have the sum of n and m from about four to about 5000 where R is a C₁-C₂₀ alkyl group or a C₆-C₁₂ aryl group. Some specific examples include alkylhydridosiloxanes, such as methylhydridosiloxanes, ethylhydridosiloxanes, propylhydridosiloxanes, t-butylhydridosiloxanes, phenylhydridosiloxanes; and alkylhydridosilsesquioxanes, such as methylhydridosilsesquioxanes, ethylhydridosilsesquioxanes, propylhydridosilsesquioxanes, t-butylhydridosilsequioxanes, phenylhydridosilsesquioxanes and combinations thereof.

In some contemplated embodiments, specific organohydridosiloxane resins utilized herein have the following general formulas:

[H—Si_{1.5}]ₙ[R—SiO_{1.5}]ₘ Formula (1)

[H_{0.5}—Si_{1.5-1.8}]ₙ[R_{0.5-1.0}—SiO_{1.5-1.8}]ₘ Formula (2)

[H_{0-1.0}—Si_{1.5}]ₙ[R—SiO_{1.5]}ₘ Formula (3)

[H—Si_{1.5}]ₓ[R—SiO_{1.5}]_{y}[SiO₂]_{z} Formula (4)

wherein:
the sum of n and m, or the sum or x, y and z is from about 8 to about 5000; R is selected from substituted and unsubstituted, normal and branched alkyls (methyl, ethyl, butyl, propyl, pentyl), alkenyl groups (vinyl, allyl, isopropenyl), cycloalkyls, cycloalkenyl groups, aryls (phenyl groups, benzyl groups, naphthalenyl groups, anthracenyl groups and phenanthrenyl groups), and mixtures thereof.

Some of the contemplated compounds and methods of producing those compounds previously mentioned are taught by commonly assigned U.S. Pat. No. 6,143,855 issued Nov. 17, 2000 and U.S. Pat. No. 7,011,889 issued Mar. 14, 2006 and organosilsesquioxanes taught by commonly assigned WO 01/29052 published Apr. 26, 2001. Other contemplated compounds are described in the following issued patents and pending applications, which are herein incorporated by reference in their entirety: WO 2000/077575 published Dec. 21, 2000; U.S. Pat. No. 6,268,457 issued Jul. 31, 2001; U.S. application Ser. No. 09/491166 filed Jun. 10, 1999; U.S. Pat. No. 6,365,765 issued on Apr. 2, 2002; U.S. Pat. No. 6,268,457 issued on Jul. 31, 2001; U.S. Pat. No. 6,824,879 issued Nov. 20, 2004; WO 2000/041231 published Jul. 13, 2000; U.S. Pat. No. 6,177,199 issued Jan. 23, 2001; U.S. Pat. No. 6,358,559 issued Mar. 19, 2002; U.S. Pat. No. 6,218,020 issued Apr. 17, 2001; U.S. Pat. No. 6,361,820 issued Mar. 26, 2002; U.S. Pat. No. 6,218,497 issued Apr. 17, 2001; U.S. Pat. No. 6,359,099 issued Mar. 19, 2002; U.S. Pat. No. 6,143,855 issued Nov. 7, 2000; U.S. Pat. No. 6,512,071 issued Jan. 28, 2003; and U.S. application Ser. No. 60/043,261). Silica compounds contemplated herein are those compounds found in U.S. Issued Pat. Nos. 6,022,812; 6,037,275; 6,042,994; 6,048,804; 6,090,448; 6,126,733; 6,140,254; 6,204,202; 6,208,041; 6,318,124 and 6,319,855.

### Catalysts

At least one catalyst may be added to the at least one silicon-based compound. In some embodiments, suitable catalysts are heat-activated catalysts. As used herein, the term “catalyst” means any substance that affects the rate of the chemical reaction by lowering the activation energy for the chemical reaction. In some cases, the catalyst will lower the activation energy of a chemical reaction without itself being consumed or undergoing a chemical change. These condensation catalysts are often only activated at a particular temperature, such as an elevated temperature. Thus, at one temperature (such as room temperature) the composition maintains a low molecular weight, thus enabling good planarization ability over a surface. When the temperature is elevated (such as to greater than 50° C.), the condensation catalyst catalyzes an Si—OH condensation reaction, which results in a more dense structure and, in some cases, improved performance overall. Contemplated condensation catalysts comprise those catalysts that can aid in maintaining a stable silicate solution. Contemplated metal-ion-free catalysts may comprise onium compounds and nucleophiles. The catalyst may be, for example an ammonium compound (such as quaternary ammonium salts), an amine, a phosphonium compound or a phosphine compound.

In some embodiments, contemplated catalysts include those catalysts that are relatively molecularly “small” or that produce relatively small cations, such as quaternary ammonium salts. In some embodiments, contemplated catalysts include tetramethylammonium acetate (TMAA), tetramethylammonium hydroxide (TMAH), tetrabutylammonium acetate (TBAA), cetyltrimethylammonium acetate (CTM), tetramethylammonium nitrate (TMAN), other ammonium-based catalysts, amine-based and/or amine-generating catalysts and combinations thereof. Other appropriate catalysts include (2-hydroxyethyl)trimethylammonium chloride, (2-hydroxyethyl)trimethylammonium hydroxide, (2-hydroxyethyl)trimethylammonium acetate, (2-hydroxyethyl)trimethylammonium formate, (2-hydroxyethyl)thrimethylammonium nitrate, (2-hydroxyethyl)trimethylammonium benzoate, tetramethylammonium formate and combinations thereof. In some contemplated embodiments, TMAN is used and can be obtained by either dissolving TMAN in water or by converting TMAA or TMAH to TMAN by using nitric acid.

Other suitable catalysts include (carboxymethyl)trimethylammonium chloride, (carboxymethyl)trimethylammonium hydroxide, (carboxymethyl)trimethylammonium formate and (carboxymethyl)trimethylammonium acetate. “(carboxymethyl)trimethylammonium” is also known as “Betaine”. One advantage to utilizing betaine and choline, in addition to improved catalytic activity, is that they are natural products which are used in food or food supplements.

### Solvents

At least one solvent is added to the at least one silicon-based compound and the at least one catalyst. Contemplated solvents include any suitable pure or mixture of organic molecules that are volatilized at a desired temperature and/or easily solvates the components discussed herein. The solvent may also comprise any suitable pure or mixture of polar and non-polar compounds. As used herein, the term “pure” means that component that has a constant composition. For example, pure water is composed solely of H₂O. As used herein, the term “mixture” means that component that is not pure, including salt water. As used herein, the term “polar” means that characteristic of a molecule or compound that creates an unequal charge, partial charge or spontaneous charge distribution at one point of or along the molecule or compound. As used herein, the term “non-polar” means that characteristic of a molecule or compound that creates an equal charge, partial charge or spontaneous charge distribution at one point of or along the molecule or compound.

Contemplated solvents are also those solvents that can, alone or in combination, modify the viscosity, intermolecular forces and surface energy of the solution in order to, in some cases, improve the gap-filling and planarization properties of the composition. It should be understood, however, that suitable solvents may be those solvents that influence the profile of the composition in other ways, such as by influencing the crosslinking efficiency, influencing the thermal stability, influencing the viscosity, and/or influencing the adhesion of the resulting layer or film to other layers, substrates or surfaces.

The at least one solvent may comprise those solvents that are considered part of the hydrocarbon family of solvents. Hydrocarbon solvents are those solvents that comprise carbon and hydrogen. It should be understood that a majority of hydrocarbon solvents are non-polar; however, there are a few hydrocarbon solvents that could be considered polar. Hydrocarbon solvents are generally broken down into three classes: aliphatic, cyclic and aromatic. Aliphatic hydrocarbon solvents may comprise both straight-chain compounds and compounds that are branched and possibly crosslinked, however, aliphatic hydrocarbon solvents are not considered cyclic. Cyclic hydrocarbon solvents are those solvents that comprise at least three carbon atoms oriented in a ring structure with properties similar to aliphatic hydrocarbon solvents. Aromatic hydrocarbon solvents are those solvents that comprise generally three or more unsaturated bonds with a single ring or multiple rings attached by a common bond and/or multiple rings fused together. Contemplated hydrocarbon solvents include toluene, xylene, p-xylene, m-xylene, mesitylene, solvent naphtha H, solvent naphtha A, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosine, isobutylbenzene, methyinaphthalene, ethyltoluene, ligroine. Particularly contemplated solvents include, but are not limited to, pentane, hexane, heptane, cyclohexane, benzene, toluene, xylene and mixtures or combinations thereof.

The at least one solvent may comprise those solvents that are not considered part of the hydrocarbon solvent family of compounds, such as ketones, such as acetone, diethyl ketone, methyl ethyl ketone and the like, alcohols, esters, ethers and amines. Other contemplated solvents include ethyl lactate, propylene glycol monomethyl ether acetate (PGMEA) or a combination thereof. In yet other contemplated embodiments, the at least one solvent may comprise a combination of any of the solvents mentioned herein.

The at least one solvent may be present in solution in an amount less than about 90% by weight. In some embodiments, at least one solvent may be present in solution in an amount from about 50 to 90% by weight. In other embodiments, at least one solvent may be present in solution in an amount from about 55 to 85% by weight. In yet other embodiments, at least one solvent may be present in solution in an amount from about 65 to 85% by weight. The determination of what is the appropriate amount of solvent to add to composition depends on a number of factors, including: a) thicknesses of the desired layers or films, b) desired concentration of the solids in the composition, c) application technique of the composition and/or d) spin speeds, when spin-coating techniques are utilized. In addition, the higher the solid concentration (or the resin or polymer) is in the formulation, the higher the viscosity. Spin and spray coaters can handle compositions with low viscosity (i.e. 3 centipoises), but slot die or slit coaters often need compositions having a high viscosity. Hence, the solid content should be increased (or reduce solvent amount) to get viscous material—i.e. 9 centipoises. In addition, the viscous formulation or formulation with higher solid content will give thicker film (>2 μm).

The solvents used herein may comprise any suitable impurity level. In some embodiments, the solvents utilized have a relatively low level of impurities, such as less than about 1 ppm, less than about 100 ppb, less than about 10 ppb, less than about 1 ppb, less than about 100 ppt, less than about 10 ppt and in some cases, less than about 1 ppt. These solvents may be purchased having impurity levels that are appropriate for use in these contemplated applications or may need to be further purified to remove additional impurities and to reach the less than about 10 ppb, less than about 1 ppb, less than about 100 ppt or lower levels that suitable and/or desired.

### Composition-Modifying Constituents

Optionally, the compositions may further comprise at least one composition-modifying constituent, such as at least one surfactant, at least one adhesion promoter, at least one crosslinking agent, at least one other additive or a combination thereof. These composition-modifying constituents are designed to influence the properties of the compositions, coatings, layers and/or films. Contemplated properties which may be influenced, are surface tension, adhesion to other layers or surfaces, viscosity, density, transmittance/transparency or a combination thereof.

At least one surfactant is considered to be one of the contemplated composition-modifying constituents. Surfactants may be added to lower surface tension. As used herein, the term “surfactant” means any compound that reduces the surface tension when dissolved in H₂O or other liquids, or which reduces interfacial tension between two liquids, or between a liquid and a solid. Contemplated surfactants may include at least one anionic surfactant, cationic surfactant, non-ionic surfactant, Zwitterionic surfactant or a combination thereof. The surfactant may be dissolved directly into the composition or may be added with one of the compositions components (the at least one silicon-based compound, the at least one catalyst, the at least one solvent) before forming the final composition. Contemplated surfactants may include: polyether modified polydimethylsiloxanes such as BYK 307 (polyether modified poly-dimethyl-siloxane, BYK-Chemie), sulfonates such as dodecylbenzene sulfonate, tetrapropylenebenzene sulfonate, dodecylbenzene sulfonate, a fluorinated anionic surfactant such as Fluorad FC-93, and L-18691 (3M), fluorinated nonionic surfactants such as FC-4430 (3M), FC-4432 (3M), and L-18242 (3M), quaternary amines, such as dodecyltrimethylammonium bromide or cetyltrimethylammonium bromide, alkyl phenoxy polyethylene oxide alcohols, alkyl phenoxy polyglycidols, acetylinic alcohols, polyglycol ethers such as Tergitol TMN-6 (Dow) and Tergitol minifoam 2x (Dow), polyoxyethylene fatty ethers such as Brij-30 (Aldrich), Brij-35 (Aldrich), Brij-58 (Aldrich), Brij-72 (Aldrich), Brij-76 (Aldrich), Brij-78 (Aldrich), Brij-98 (Aldrich), and Brij-700 (Aldrich), betaines, sulfobetaines, such as cocoamidopropyl betaine, and synthetic phospholipids, such as dioctanoylphosphatidylcholine and lecithin and combinations thereof.

Other contemplated surfactants include those found in U.S. Issued Pat. Nos. 5,858,547 and 6,517,951 issued to Hacker et al., which are commonly-owned, assigned and incorporated herein by reference in their entirety. As contemplated herein, the at least one surfactant may be present in solution in an amount less than about 1% by weight. In some embodiments, the at least one surfactant may be present in solution in an amount from about 0.001% to about 1% by weight. In other embodiments, the at least one surfactant may be present in solution in an amount from about 0.001% to about 0.25% by weight. In some embodiments, at least two surfactant constituents may be present in solution. The determination of what is the appropriate amount of a composition-modifying constituent to add to composition depends on a number of factors, including: a) minimizing defects in the film, and/or b) balancing the film between good adhesion and desirable film properties.

In other embodiments, at least one adhesion promoter may be added to the composition, alone or with the at least one surfactant, in order to influence the ability of the layer, coating or film to adhere to surrounding substrates, layers, coatings, films and/or surfaces. In some contemplated embodiments, the at least one adhesion promoter comprises at least one of the following characteristics: a) is thermally stable after heat treatment, such as baking, at temperatures generally used for optoelectronic component manufacture, and/or b) can surprisingly act as an adhesion promoter by promoting electrostatic and coulombic interactions between layers of materials, as well as promoting understood Van derWaals interactions in some embodiments.

In a contemplated embodiment, the addition of at least one adhesion promoter, such as at least one weak acid/weak base, at least one weak acid/strong base, at least one strong acid/strong base, at least one strong acid/weak base, at least one amine base, at least one amine salt or a combination thereof increases the electrostatic and coulombic interaction. Contemplated adhesion promoters include aminopropyl triethoxysilane (APTEOS) nitrate, APTEOS acetate, APTEOS sulfonate, APTEOS methanesulfonate, APTEOS triflate, APTEOS tosylate, APTEOS nonafluorobutane-1-sulfonate (nfbs) or any other amine salt or combination of amine salts. Suitable amine bases comprise ammonium, pyridine, aniline, TMAH, CTAH, TBAH, APTEOS or a combination thereof. Other contemplated adhesion promoters include 3-(triethoxysilyl)propylsuccininc anhydride, dimethyldihydroxy silane, methylphenyl dihydroxysilane or combinations thereof. As contemplated herein, the at least one adhesion promoter may be present in solution in an amount less than about 20% by weight. In some embodiments, the at least one adhesion promoter may be present in solution in an amount from about 0.001% to about 20% by weight. In other embodiments, the at least one adhesion promoter may be present in solution in an amount from about 0.26% to about 2.6% by weight. In some embodiments, at least two adhesion promoters may be present in solution.

At least one crosslinking agent may be added to the composition. As used herein, the term “crosslinking” refers to a process in which at least two molecules, or two portions of a long molecule, are joined together by a chemical interaction or reaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules. The chemical reaction may take place between two identical, or non-identical reactive groups, which may be located on the same or on two separate backbones. It is also contemplated that the reactive groups may react with one or more than one exogenous crosslinking molecules to crosslink the at least one silicon-based polymer. It should be understood that while the at least one catalyst lowers the activation energy of the composition in order to effect crosslinking of the at least one silicon-based compound, the at least one crosslinking agent may be added in order to continue crosslinking the at least one silicon-based compound in order to increase the crosslinking density of the coating, layer or film.

With respect to the properties of the compositions, coatings, films, layers or combination thereof, it may be beneficial to either lower or increase one or both the viscosity and the intermolecular forces constituent in order to optimize the gap-filling and planarization properties for the particular end use. One method used to modify the planarization composition is to modify and/or replace the at least one solvent, wherein the at least one solvent is compatible with the at least one silicon-based compound and modifies at least one of the intermolecular forces or surface forces components of the planarization composition to which it is added. Another method is to add at least one composition-modifying constituent, such as those mentioned herein. As used herein, the phrase “intermolecular forces” means those bonding or non-bonding forces, such as Van der Waals, electrostatic, steric, coulombic, hydrogen bonding, ionic, covalent, dipole-dipole, dispersion, magnetic attraction and combinations thereof, that take place between two or more parts of matter or components, such as a planarization composition and a surface, a planarization composition and another layer of material, molecules that make up the planarization composition and combinations thereof.

In other contemplated embodiments, the at least one solvent, the at least one composition-modifying constituent or a combination thereof modifies the apparent viscosity by at least about 10%. In other contemplated embodiments, the apparent viscosity is modified by at least about 20%. In yet other contemplated embodiments, the apparent viscosity is modified by at least about 30%. As used herein, the phrase “apparent viscosity” means the characteristic of fluid's internal resistance to flow and which equals the ratio of stress to the rate of strain. In micron and submicron trenches, the apparent viscosity represents the integral effect of surface forces and usually decreases from the nominal viscosity due to the size effect where the ratio between surface force and body force is large. Also as used herein, the phrase “nominal viscosity” means that viscosity that is the bulk fluid property determined from a commercially available viscometer, such as a Brookfield viscometer, and is calculated from measurements of forces and velocities when liquid is Newtonian.

In yet other embodiments, a surface forces component, such as an interfacial surface tension, is created by the planarization composition and the interaction of the planarization composition with the surface, substrate or wafer. Solvents and composition-modifying constituents contemplated herein can modify the interfacial surface tension by at least about 10% when compared to a conventional planarization composition known to one of ordinary skill in the art of layered materials. In some embodiments, the at least one solvent, the at least one composition-modifying constituent or combination thereof can modify the interfacial surface tension by at least about 20% when compared to a conventional planarization composition. In yet other embodiments, the at least one solvent, the at least one composition-modifying constituent or combination thereof can modify the interfacial surface tension by at least about 30% when compared to a conventional planarization composition.

As a general example, a silicon-based compound, such as a phenylsilsesquioxane oligomer-containing formulation, is applied to a silicon substrate and cured to form a polymer film. The phenylsilsesquioxane oligomer has a molecular weight of 800-1200 AMU. The formulation can be prepared by dissolving the phenylsilsesquioxane oligomer into propylene glycol monomethyl ether acetate (PGMEA) in an amount varying between 15 and 45 percent by weight. A condensation catalyst (tetramethylammonium nitrate) is added in a concentration ranging from 15-250 ppm. A surfactant (such as BYK 307 from BYK-Chemie) may be added to the formulation to improve film quality of thicker films. The formulation is then applied to the substrate by spinning, slot die coating, dipping, or spraying. The film is formed on the substrate by baking between 150 and 300° C. to remove solvent, followed by a curing step of between 150 and 400° C. to induce crosslinking of the phenylsilsesquioxane. The thickness of the resulting film varies between 0.3 and 2.5 um, depending on the weight percent phenylsilsesquioxane content of the formulation. Film properties include low outgassing, good planarization, high optical transparency, high thermal stability, high refractive index and good electrical insulation (k˜3). These properties are desirable for use in various optoelectronic applications, such as flat panel displays. Contemplated materials, coatings, layers and/or films may have a relatively high refractive index. In some embodiments, the refractive index is greater than about 1.5.

### Uses of the Compositions in Optoelectronic Applications

Optoelectronic devices are also contemplated herein, comprising at least one light-transmissive film or layer produced by providing at least one silicon-based compound, providing at least one catalyst, providing at least one solvent, blending the at least one silicon-based compound, the at least one catalyst and the at least one solvent to form a composition, applying the composition to a suitable surface, and at least partially activating the at least one catalyst in order to form the light-transmissive film or layer. It is contemplated that an optoelectronic device may comprise one or more light-transmissive films or layers, such as those described herein, and those light-transmissive films or layer may comprise the same chemical composition or one that is slightly different from another light-transmissive film or layer. In other embodiments, at least one composition-modifying constituent may be added to the composition.

Contemplated compositions are applied to suitable surfaces, such as layers, films or substrates depending on the projected end-use of the film formed from the composition. Surfaces contemplated herein may comprise any desirable substantially solid material, such as a glass, stainless steel or plastic substrate found in the optoelectronic manufacturing industry. The surfaces may be coated or uncoated, patterned or unpatterned, and may reside anywhere in the optoelectronic device, such as on the top of a TFT structure, between or in TFT structures, on top of a stainless steel or plastic substrate above which TFT or any suitable semiconductor device structures (or other structures) are placed, adjacent a color filter in an LCD, adjacent an OLED device or adjacent any other surface within a flat panel or other display or optoelectronic device. Some contemplated surfaces comprise a non-planar surface topography and other contemplated surfaces that have already been planarized. Particularly desirable surfaces comprise films, glass, ceramic, plastic, metal or coated metal, or composite material. Surfaces comprise at least one layer and in some instances comprise a plurality of layers. In other embodiments, the surface comprises a material common in the optoelectronic industries. Suitable surfaces contemplated herein may also include another previously formed layered stack, other layered component, or other component altogether.

The at least one catalyst is activated at a suitable point in the production of the layered material, device, film or display, thereby forming the light-transmissive film or layer. In some embodiments, the composition is applied to a suitable surface and the at least one catalyst is at least partially activated. By “at least partially activated”, the at least one catalyst may be activated in that it converts the composition to a partially crosslinked gelled film, but has not been activated as such to convert the composition to a fully crosslinked film. In other embodiments, the composition is at least partially activated before application to a surface, substrate, layer or film. In yet other embodiments, the composition is applied to a suitable surface, layer, film or substrate and the at least one catalyst is fully activated thus resulting in a crosslinked and dense film or layer. Contemplated catalysts may be activated by any suitable device, method or action, including by applying heat, light, vibration or another chemical compound.

Compositions contemplated herein may be coated onto a surface by any suitable method, including continuous deposition techniques such as spin coating, gravure coating, curtain coating, dip coating, slot-die coating, spray coating, and continuous nozzle coating; and discontinuous deposition techniques such as ink jet printing, gravure printing, and screen printing.

In some contemplated compositions, where the composition comprises at least one sufficiently light-transmissive crosslinkable composition, wherein the composition comprises at least one silicon-based material, at least one crosslinking agent and at least one solvent, the composition after a cure or curing step having at least one cure temperature and at least one cure time has a weight loss of less than about 2% during further processing at or below the cure temperature. In other embodiments, this weight loss is less than about 1%. In some embodiments, the at least one cure temperature ranges from about 150° C. to about 400° C., and the at least one cure time is less than about 2 hours.

The films produced by the compositions and processes described herein may have one or more advantages over those previously known to the art, including improved dielectric breakdown strength also known as electric field to breakdown (FBD), which enables the film to be used in optoelectronic applications. In the manufacture of optical devices such as flat panel displays, gate dielectrics, planarization layers and passivation layers may need to have a FBD of at least about 2.5 MV/cm, and in some embodiments, greater breakdown fields are desirable. A transparency to light in the range of about 400 nm to about 800 nm of at least about 90% is desirable in contemplated films. In some embodiments, the films, coatings and layers have a transparency to light of at least about 95%. In some embodiments, the films, coatings and layers have a transparency to light of at least about 98%. In other embodiments, the films, coatings and layers have a transparency to light of at least about 99%. In some embodiments, the films, coatings and layers have a degree of planarization of above 90% over topographies. In other embodiments, the films, coatings and layers have root mean square surface roughness lower than 10 nm or Angstroms.

In optoelectronic devices and displays, conformal coatings are used as insulators for an interlayer dielectric, such as CVD SiO₂ and SiN. Using a planarizing/gap filling material is desirable as it avoids sharp corners that can create shorts in subsequent metallization steps. For the passivation layer, SiN/SiO₂ can also be used, but using a planarizing material increases the area of the pixel electrode and therefore increases the brightness of the display. Sometimes for the passivation layer or planarizing layer, organic materials are used, such as benzocyclobutene (BCB) or a photoimageable acrylic. In the case of BCB, materials disclosed herein have a higher thermal stability. In the case of the photoimageable acrylic resin, materials disclosed herein have a higher thermal stability, and also have higher transparency. High thermal stability is often very desirable, as it prevents outgassing that can cause adhesion problems as well as damage moisture sensitive components in the finished device.

### Thin Film Transistors (TFTs):

Compositions, coatings, materials, films and layers disclosed herein may be used as interlevel (between 1^{st} and second metal layers, or between second metal and pixel electrode layer) or intralevel (between metal lines or contacts in the same level) dielectric (ILD) layers in thin film transistors, such as amorphous silicon thin film transistors, low temperature polysilicon transistors, crystalline silicon transistors, organic transistors, organic field effect transistors or static induction transistors. In all these devices, contemplated compositions are used as an intralayer dielectric between source and drain (S/D) contacts, an interlayer or interlevel dielectric between gate and S/D contacts, between gate and pixel electrode in LCDs or between any two metallic conducting regions. The contemplated compositions may also replace the insulator (known as gate dielectric and the material commonly used in current devices is SiN) above the gate. The contemplated compositions, films and/or layers may also function as passivation layers and planarization layers in these devices.

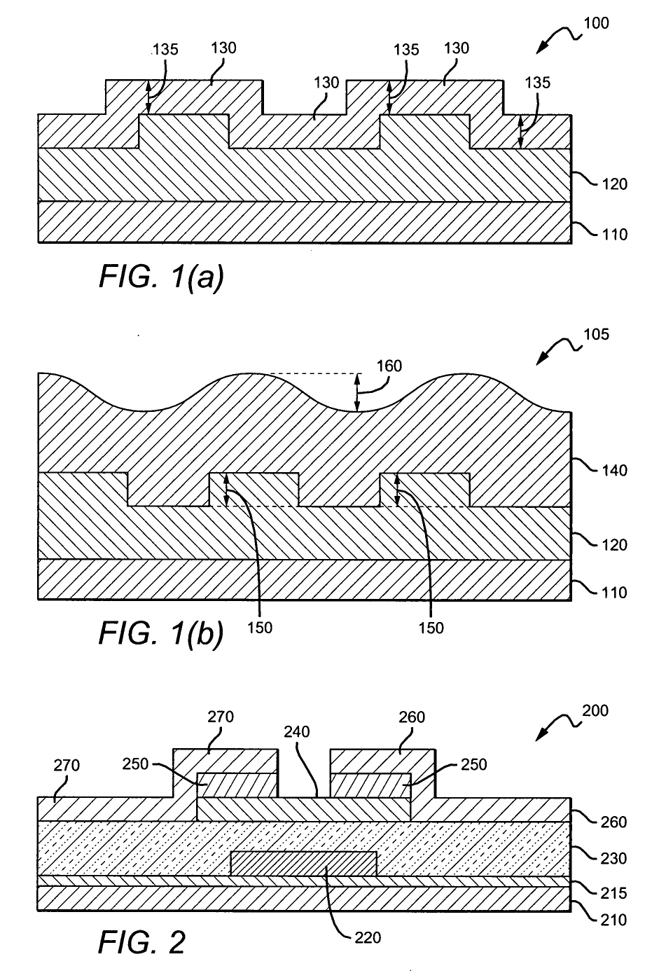

Planarizing layer differs from conformal layers such as chemical vapor deposited silicon nitride in thickness variation across the surface as shown in FIGS. 1(a) and 1(b). FIG. 1(a) shows a cross-section of a conformal coated patterned substrate (100) comprising a substrate (110), a surface (120) with topography and a conformal layer or coating comprising SiNₓ applied by chemical vapor deposition (CVD). Conformal layers (130) give rise to uniform thickness (135) all over the surface (120) thereby keeping the topography of the surface (120) intact as shown in FIG. 1(a). FIG. 1(b) shows a cross-section of a planarized substrate (105) comprising a substrate (110) and a surface (120) with topography and a planarizing layer (140). Planarizing layers give rise to different thicknesses in different regions (lower thickness on top of hills and higher thickness in the valleys) such that the topography of the surface is altered and the surface becomes almost flat as shown in FIG. 1(b). The degree of planarization (DOP, expressed in percentage) is the difference between the initial height of the feature on a given surface before coating (150) and the dip (160) in the planarizing coating (from the top surface of coating) at the valley region normalized to the initial height of the feature. Layers that yield greater than 90% DOP are considered to be good planarizing layers. Usually the amount of solid or resin content in the formulation or the amount of solvent is adjusted, or the solvent(s) is(are) changed to achieve a flat surface for a given topography.

Thin film transistors, being the heart of any flat panel screen, in general comprise three terminals known as gate, source and drain. FIG. 2 shows the cross section of a typical thin film transistor device (200) in which a contemplated formulation is used as a gate dielectric (230). The substrate (210) could be glass, plastic or metal. A metal layer is formed on the top of a substrate (210) usually by physical vapor deposition process (such as sputtering) and patterned to form the gate metal (220). When the gate dielectric material (230) is coated on a substrate (210) patterned with a gate metal (220), the dielectric material (230) planarizes the surface topography as shown in FIG. 2. On top of the gate dielectric, amorphous silicon (240) is deposited. Source and drain regions in a-Si are doped with n+ to achieve a low contact resistance. The source (270) and drain (260) contacts are formed on the n+ doped (250) regions of amorphous silicon (240). In general, whenever a planarizing layer is used, the surface topography is largely reduced.

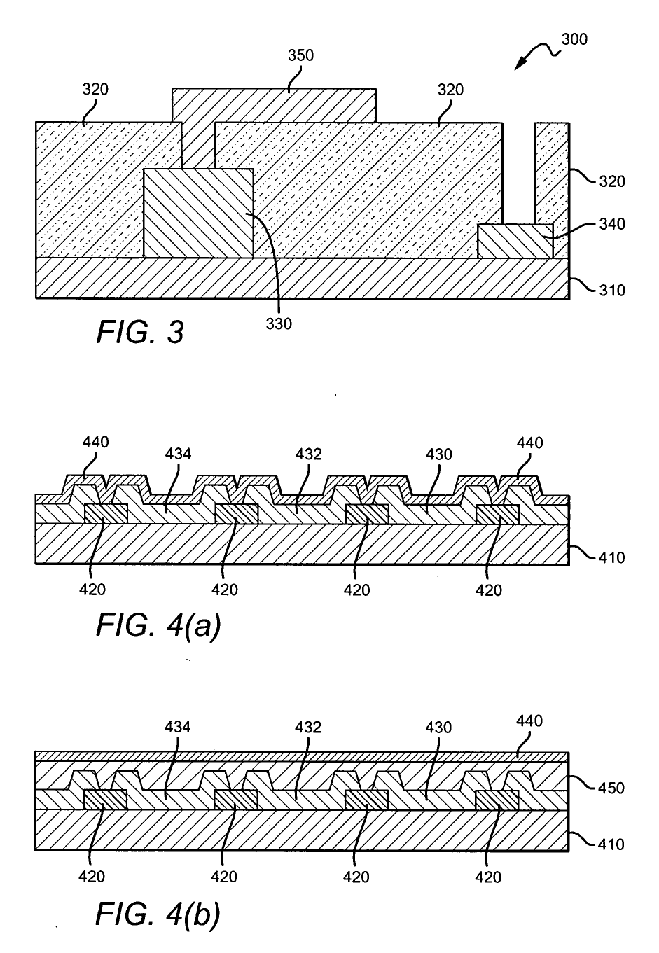

In a contemplated device (300), after building the TFT regions (330) on a substrate (310), the surface is planarized using the contemplated formulation (320) as shown in FIG. 3. This layer (320) is usually known as interlayer dielectric as it exists between the first metal layer (340) (which also forms the gate in TFT regions) and the pixel electrode (350). The pixel electrode (350) is connected to the drain (not shown) of the TFT. This layer (320) is also called passivation layer as it protects the TFT regions during further processing steps and it isolates the liquid crystal region from the TFT region.

### Color Filter in Liquid Crystal Displays

Among flat panel displays, liquid crystal display (LCD) devices have been commonly used due to their thin profile, light weight, and low power consumption. In LCD systems, the liquid crystal molecules are oriented in different directions to selectively allow (or block) light passage and thereby achieve image displaying. The color to the image is imparted by the color filter screen. A color filter screen is a contemplated end use for the compositions, layers and films disclosed herein.

FIG. 4(a) shows the cross section of a typical color filter and FIG. 4(b) shows how contemplated materials are used in a color filter. In general, a color filter screen in a LCD is fabricated by first depositing a chromium-based or resin-based black matrix (420) on a substrate (410) and patterning it. This step is followed by forming three primary color regions (430, 432, 434) by depositing the respective resins and patterning to define red, green and blue regions. A transparent conducting electrode (440) usually indium tin oxide (ITO)—common electrode for liquid crystals to function—is deposited on top of the color patterns interspersed with black matrix. The common electrode (440) follows the topography of the underlying color regions. A polyimide layer is deposited on top of the electrode (not shown) to complete the color filter screen. Because of the topography in ITO, differential field results leading to differential response of liquid crystals. ITO deposition is a sputtering process, which may also damage color resins. To protect the three primary color regions the surface is covered by an overcoat layer (450) as shown in FIG. 4(b). This overcoat layer (450) may comprise contemplated formulations, as described throughout this disclosure. This layer in addition to protecting color regions, planarizes the surface. The common electrode (440) deposited on top of this overcoat is flat and provides a uniform field to the liquid crystal in a given pixel or subpixel.

Thus, the contemplated layers, films, materials or composition may be used as a gate dielectric, inter- or intra-level dielectric, passivation and planarization layers in different regions of the TFTLCD and as color filter overcoat in color filter screens.

### Organic Light-Emitting Diode (OLED)

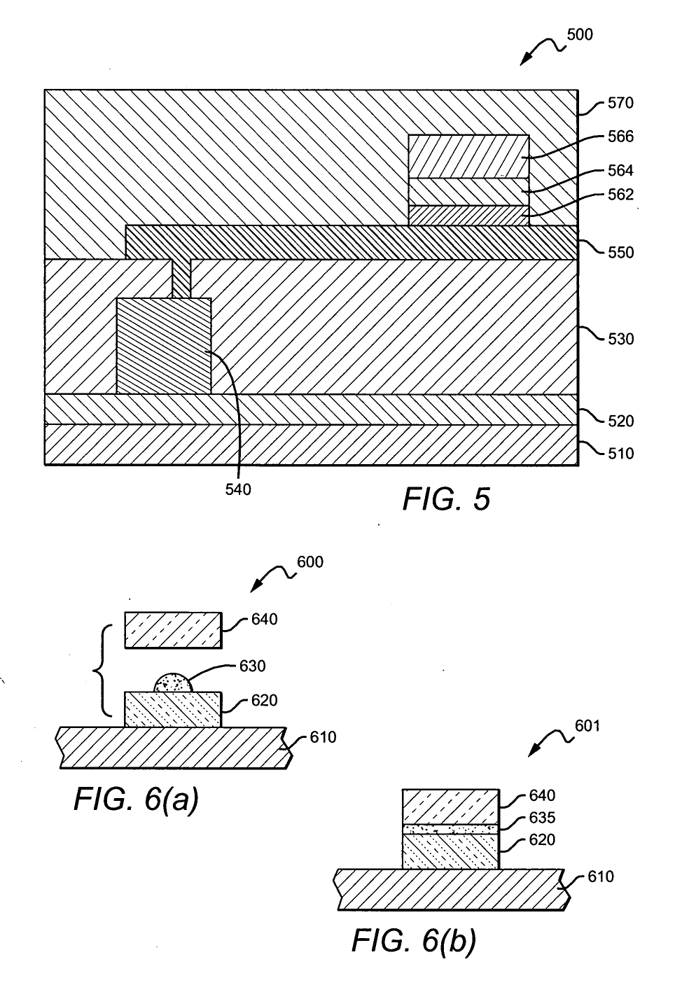

FIG. 5 shows the cross section of an active matrix organic light emitting diode (AMOLED) (500). As shown in the figure, an OLED device comprises a cathode (566) (usually Ca, Al or Ba), a light emitting polymer and an anode (usually ITO) (550). The light emitting polymer comprises a hole transport layer (562) to conduct holes and an electron transport layer (564) to transport electrons. Light is emitted when holes combine with electrons. To fabricate an AMOLED device (500), the substrate (510) is first coated with a moisture barrier layer (520). The contemplated formulation may be used for this purpose. Then the TFT regions (540) are formed on the contemplated moisture barrier layer (520). A passivation layer (530) (also called an ILD) of the contemplated formulation is deposited all over and opened at the drain region of the TFT to connect the anode (550) of OLED. This passivation layer should have moisture and O₂ diffusion barrier properties. The contemplated formulation is also deposited on top of OLED region as an encapsulation layer (570) to prevent moisture and O₂ diffusion from the top and the sides.

The OLED region needs to be completely encapsulated by such a barrier layer or plurality of barrier layers to prevent diffusion of water, oxygen or other extraneous substances in the environment. The diffusion of such species to OLED reduces the lifetime and reliability of OLED devices. The contemplated material may be used in general as oxygen and moisture diffusion barrier layers surrounding the OLED regions and in particular as encapsulation above the OLED regions and passivation layer below the anode. In AMOLED, the contemplated material can also be used as interlayer dielectric to planarize topographies, gate dielectric and passivation layer in TFT regions.

### Light Extraction Layer in Light-Emitting Diodes (LEDS)

Light-emitting diodes are two terminal devices with a p and n type semiconductors deposited on sapphire/GaN substrate with an inherent high refractive index. The pn junction emits light when biased with a certain voltage. FIG. 6 shows a schematic cross-sections of a contemplated LED (601) and the breakout of a contemplated LED (600), wherein the compositions contemplated herein may be utilized on top of the LED in top-emitting LEDs or on the substrate at the bottom for the bottom emitting LEDs (not shown). The contemplated composition, materials, films and layers are used as a light extraction layer (630 and 635). The contemplated formulation is applied on top of the LED region (620), which is on top of a substrate layer (610), as an adhesive to the lens (640)(usually made of polycarbonate) that goes on top of the LED region (620). This adhesive layer (630 and 635) is transparent and its refractive index is between the refractive indices of LED layer (620) and lens layer (640). By refractive index matching using this layer, the total internal reflection of light back into the LED region is reduced and more of the emitted light from LED is extracted to the lens (or from the substrate to outside in bottom emitting LED device architecture—not shown in figure), which reduces light intensity loss due to total internal reflection and makes the LEDs to have high brightness. Contemplated materials, coatings, layers and/or films may have a relatively high refractive index. In some embodiments, the refractive index is greater than about 1.5. These materials, coatings, layers and/or films can also achieve increased thickness without cracking, and have high thermal stability. In some embodiments, the thickness is greater than 1 μm. In other embodiments, the thickness is greater than about 2.5 μm. The contemplated composition or layer gives rise to thick films with a good adhesion between LED layers, lens and substrate layers.

### Substrate Planarization

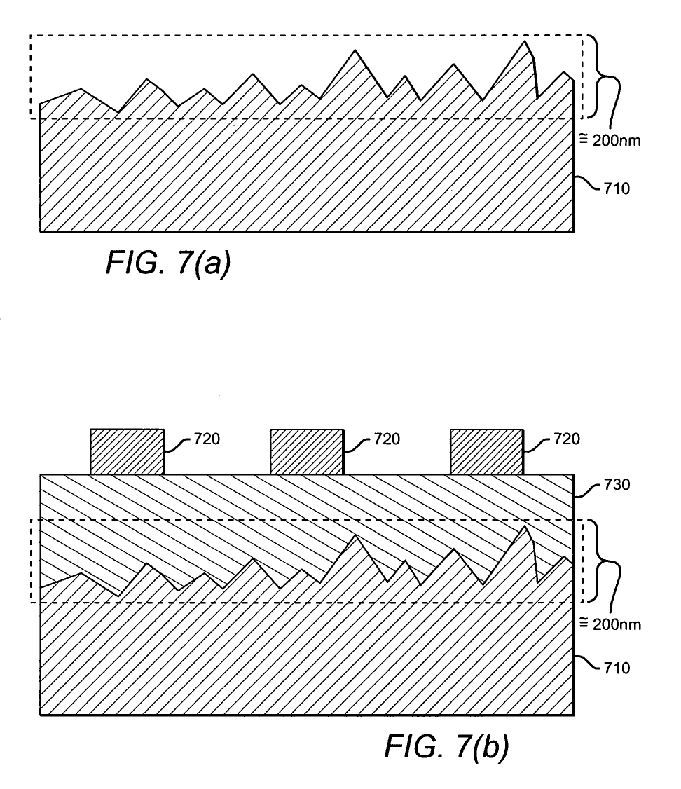

Traditionally glass substrates are used to build flat panel display screens. However flexible displays require the substrate to be flexible and therefore stainless steel or plastic substrates are the choices. These substrates (710) are in general rough (roughness of the order of a few hundred nanometers) as shown in FIGS. 7(a) and 7(b). A smooth optically flat surface is required before building any device (thin film transistor or photovoltaic cell or others) on top. If the substrate is stainless steel, a conducting substrate, it has to be isolated electrically from the devices (in this case, TFT devices represented by 720) built on top of it. The formulation, layers, and films (represented as 730) contemplated herein are used to planarize stainless steel, metal foil or plastic where transistors or any other devices would subsequently be built. On a plastic surface, the main functionalities provided by the contemplated material are surface planarization and moisture barrier properties.

### Photovoltaic Cell:

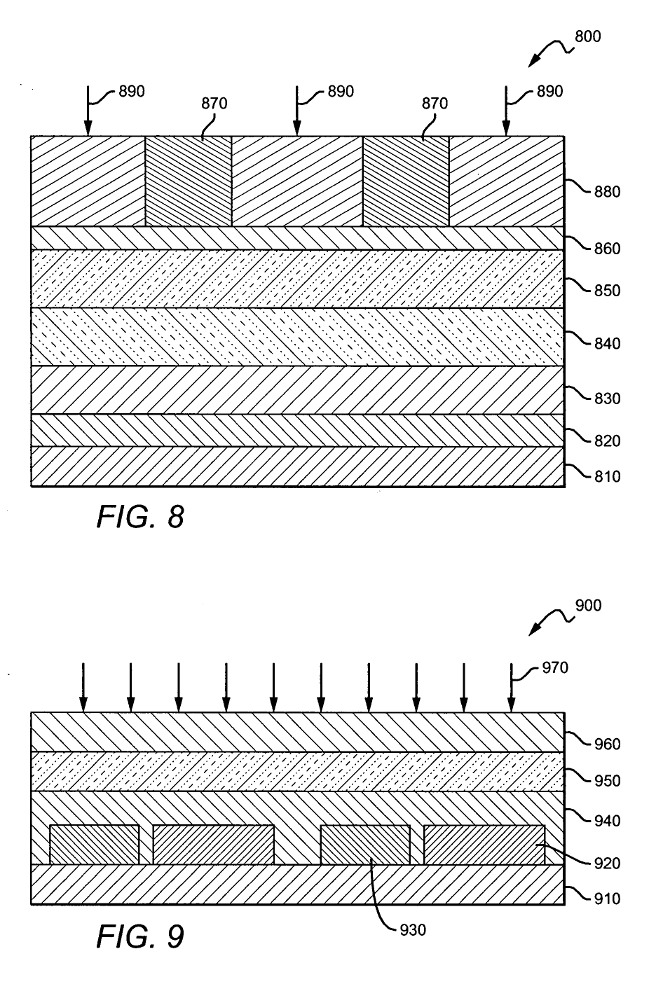

A photovoltaic cell converts light to electric current and is the heart of solar cells. The cell is constructed with two layers of semiconductors, p- and n-type sandwiched together to form a ‘pn junction’. When light is incident on the semiconductor, it is absorbed by the semiconductor and the energy is transferred to electrons in the n-type semiconductor which are then able to move through the material. For each electron, a corresponding positive charge carrier or ‘hole’, is created to maintain electrical neutrality. The electrons and holes near the pn junction are swept across in opposite directions by the action of the electric field. This separation of charge induces a voltage across the device generating electricity in external circuit. A typical cross section of a solar cell (800) is given in FIG. 8. The incident light is represented by (890). Traditionally solar cells are built on glass substrates. Recently plastic or stainless steel substrates (810) are candidates for substrates. The rough surface of these substrates is planarized using the contemplated material (820) and a back contact (830) made from metal is added to the layered material. On top of this, p-type and n-type semiconductor materials (840 and 850, respectively) are deposited. A thin layer (860) of antireflective coating is deposited on top of the shiny semiconductor (such as silicon) surface to promote more absorption of the incident light (890). The cell (800) is finished with a front contact (870) on top of n-type semiconductor. The contemplated material (880) is deposited on top of the front contact to protect metal regions (870) from environmental damage.

### X-Ray Detectors:

In general, the flat panel x-ray detector is a pixel array, comprising a million or more pixels. As shown in FIG. 9, an X-ray detector (900) in general comprises a sensor (photoconductor), capacitor and an active matrix thin film transistor addressing unit. The sensor is the photoconductor (940) that absorbs the incoming x-rays (970) and creates a corresponding electric charge which gets stored in a capacitor (920). The photoconductor (940) is coated with contemplated dielectric layers (950) and then a top electrode (960). The active matrix addressing detects the charge and sends the readout of the signal to external electronics which in turn displays the image. Each pixel in the addressing unit contains one addressing transistor (930, TFT). The layered material is built on a substrate (910), which may be glass. A thickness of around 300 to 500 μm is needed to reduce the incident X-ray energy to acceptable level that is not harmful, thin layer of amorphous silicon photoconductor alone cannot achieve this thickness. Therefore, phosphors or photoconductors are used which will convert the incident X-ray (after emerging form object to image) to either light or electron respectively; which in turn will be read out by the amorphous silicon arrays Oust like in a flat panel display). Alternately, a scintillating layer (typically CsI) and photodiode can be used instead of the photoconductor and capacitor (not shown). The materials that are used for the scintillating layer are corrosive, so the contemplated material can be used as a protecting overcoat layer between the TFT's and the scintillating layer. The contemplated layers can also be used in TFT layer as gate dielectric, ILD and passivation as described earlier.

### EXAMPLES

### Example 1

29.25 g of polyphenylsilsesquioxane (GR950F manufactured by TECHNIGLASS™) is dissolved in 70 g of PGMEA. 0.75 g of APTEOS (utilized as an adhesion promoter) is added and the solution is heated to 80° C. After 2 hours the solution is cooled and 0.83 g of glacial acetic acid is added. A TMAN solution is prepared by weighing 0.5 g of TMAN (96% powder) and adding 95.5 g of deionized water. This TMAN solution is stirred for 30 minutes at room temperature and stored at room temperature. The silsesquioxoane solution is filtered through 0.1 micron filter and then TMAN is added. The solution can then be used to form a film on a substrate by spin coating or another method.

The material described above is coated on stainless steel forming a film, which was free of ‘dewets’ after bake and cure. As used herein, the term “dewets” refers to film defects caused by poor adhesion which typically appear between film-formation and cure.

### Example 2

In this Example, a contemplated composition is prepared which comprises 30 g of phenylsilsesquioxane (GR950F manufactured by TECHNIGLASS™) and is blended with 70 g of PGMEA, along with 0.3333 g of a TMAN solution.

GR950F is a resin flake of >98% phenylsilsesquioxane. It has a MW range of 800-1200 AMU and a melting point of 60° C. The 30 g of GR950F is placed in an empty HDPE bottle, along with the 70 g of PGMEA. A TMAN solution is prepared by weighing 0.5 g of TMAN (96% powder) and adding 95.5 g of deionized water. This TMAN solution is stirred for 30 minutes at room temperature and stored at room temperature. 0.3333 g of this TMAN solution is added to the GR950F solution, which results in a total of 16.6 ppm TMAN in the final solution. The solution is kept at room temperature and stirred for 3 hours using a magnetic stirrer. The solution is filtered through a double 0.2 μm filter. The filtered solution is then spin-coated at 1500 RPM onto a silicon surface. The thickness was approximately 1 μm.

### Example 3

The composition from Example 2 was applied to an unpatterned silicon substrate and subjected to a bake and cure. The substrate and composition are baked at 160/200/300° C. for 1 minute at each temperature on a hot plate in a flowing nitrogen environment or ambient air. The baked substrate is then cured at 400° C. for 1 hour. Surface roughness (also called root mean square roughness or surface roughness) was measured with a high resolution profiler (atomic force microscope) having a probe size of less than 10 nm. Five scans were conducted where each scan had a 1, 5 and 10 μm scan size. Root mean square roughness was 5-7 Å and roughness in Z direction (the average of the five tallest peaks and 5 lowest valleys) was 16-30 Å.

### Example 4

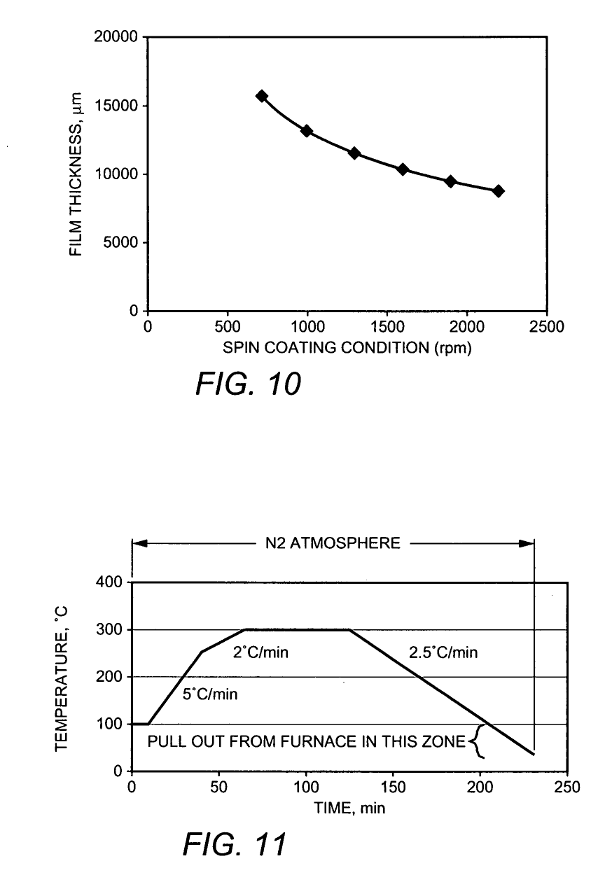

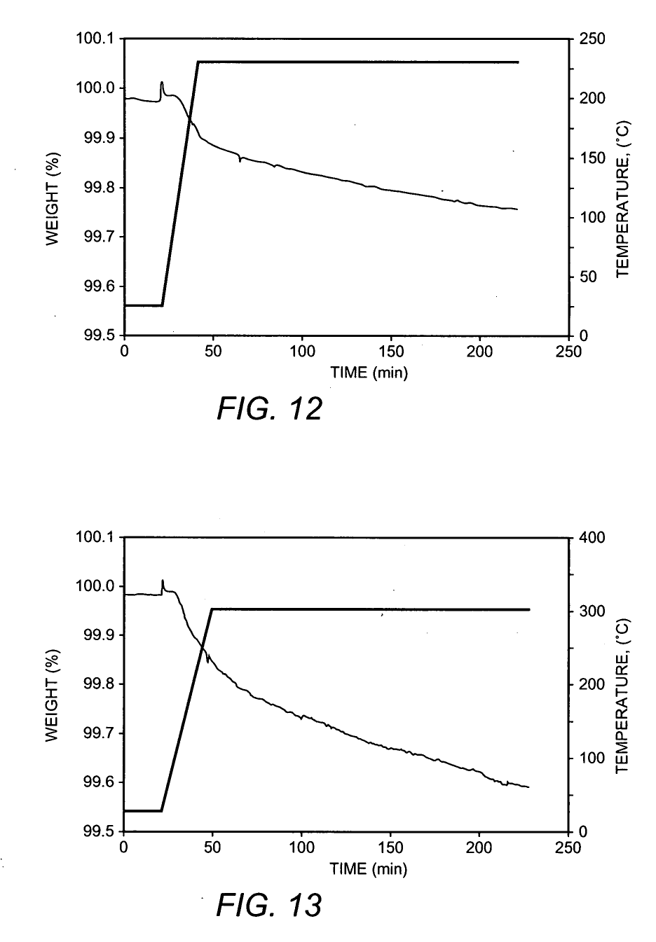

In order to identify the right concentration of the formulation that gives rise to the targeted thickness spin curves are first generated for a given formulation. FIG. 10 shows a typical post-bake spin curve. In this, film thickness is plotted as a function of rotations per minute of the wafer during spin coating. At ˜1500 rpm, the formulation gives rise to ˜1 μm film. New formulations with either higher or lower solid content can be prepared if specific rpm ranges are desired. The composition from Example 2 was spin-coated onto 8″ silicon wafers and baked at 160 C/200 C for 1 min. Some of the wafers were cured at 230° C. for an hour in N₂ environment in a furnace and others were cured in N₂ in furnace at 300° C. for an hour. The post cure thickness was 1 um and bake-to-cure shrinkage of the film was 0.5 to 0.7% in 230° and 300° C. cured films. FIG. 11 shows a contemplated curing profile for 300° C. cure. The cured film was scraped from the wafers and weight loss at high temperature was characterized by ThermoGravimetric Analysis (TGA). The TGA procedure was as follows: 1) Hold for 20 minutes at 25° C., 2) Ramp from 25° C. to corresponding cure temperature (230 and 300° C.) and hold at the maximum cure temperature for 3 hours. FIGS. 12 and 13 show respectively the weight loss of 230° C. and 300° C. cured material. The cumulative weight loss after ramp and after 1, 2 and 3 hours of holding at cure temperature is summarized in Table 1. The weight loss is very low compared to other organic and acrylic materials used as planarization layers in flat panel screens. Weight loss of ˜2 to 5% was reported for PC403 (manufactured by JSR) when heated above 230° C.

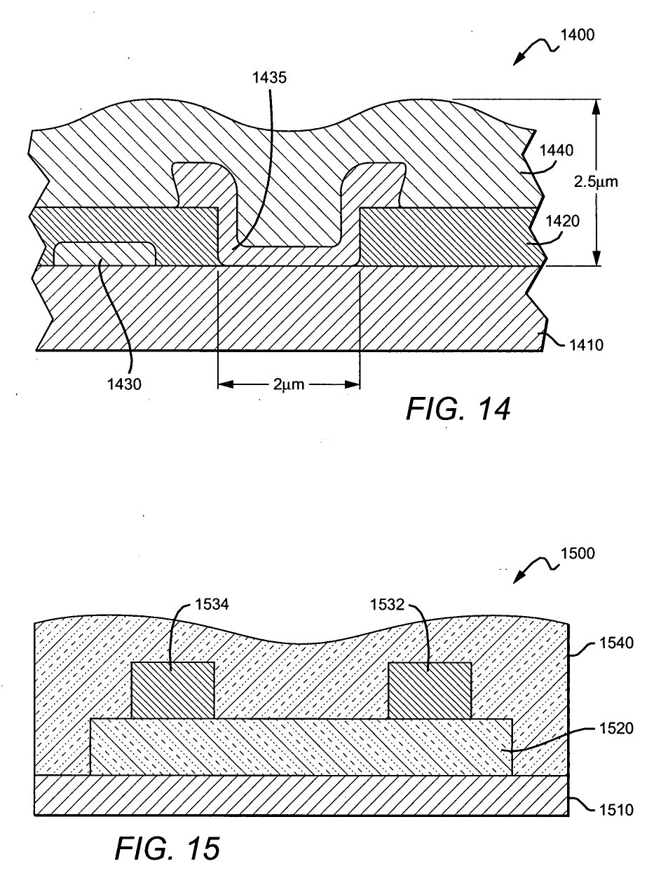

The material described in Example 2 was coated on a patterned substrate to find how well this material planarizes topographies. FIG. 14 shows a schematic depiction of a micrograph, where the surface is planarized by the contemplated material. Conformal PECVD SiO₂ (1420) was first formed on top of patterned Metal 1 (1430). The SiO₂ (1420) was etched and Metal 2 (1435) was deposited on etched regions. All of these layers are built onto a substrate 1410. The topography after Metal 2 deposition was planarized by the contemplated material (1440). The difference in layer thickness on top of and near the feature is <0.1 μm giving rise to a degree of planarization of >93%.

### Example 5

### Gate Dielectric

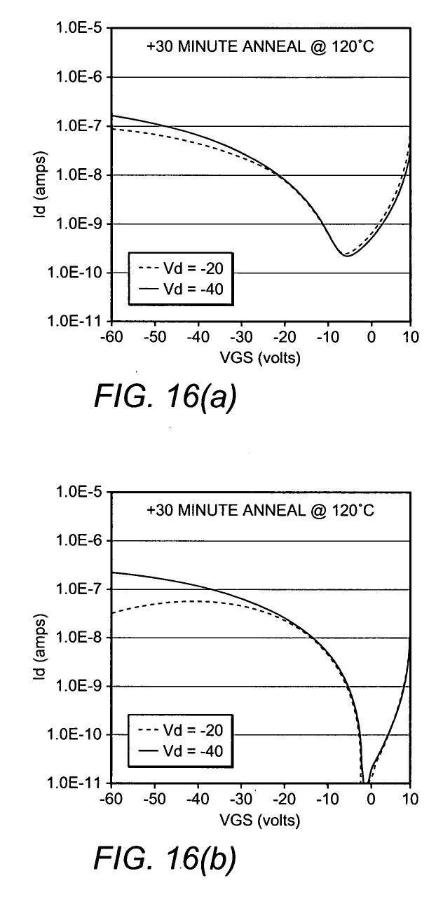

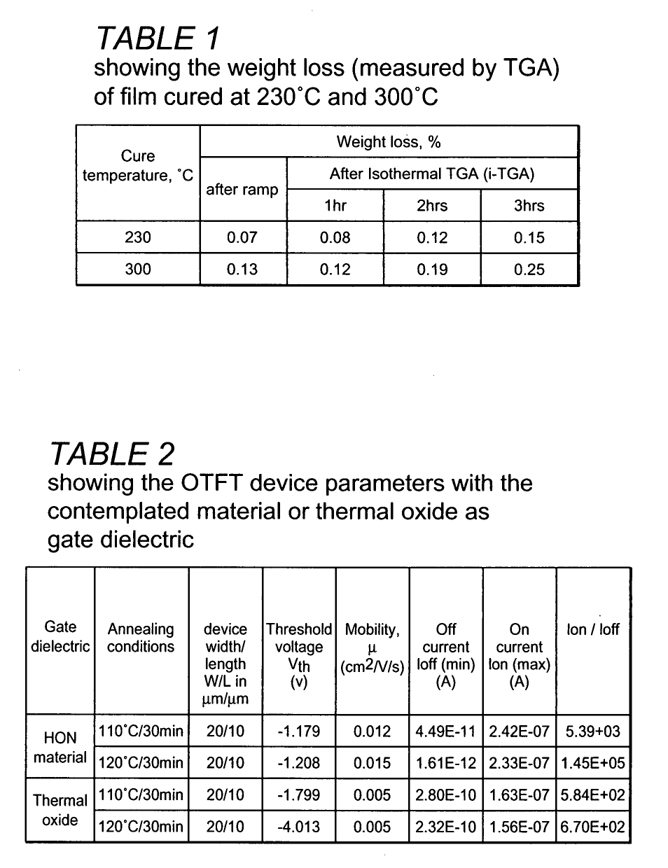

The cross-section of the organic TFT (OTFT) (1500) fabricated to test the contemplated material as gate dielectric is shown in FIG. 15. To integrate the contemplated material as gate dielectric (1520), the formulation was spin coated on p+ silicon wafer or substrate (1510) and cured at 300° C. The p+ silicon wafer functions as a gate electrode. Source/drain contacts (1532 and 1534) were fabricated on top of the gate dielectric (1520). Organic semiconductor poly-3-hexyl thiophene (1540) was deposited in a N₂ environment under a glove box and the semiconductor was annealed at different conditions shown in Table 2. Control samples were made with a thermal oxide as a gate dielectric. Measurements were made holding the samples in the glove box. FIGS. 16(a) and (b) show the device characteristics of OTFT. Drain current (Id) as a function of gate to source voltage (VGS) when drain voltage was 20 and 40V is plotted for thermal oxide in FIG. 16(a) and for a contemplated material in FIG. 16(b). The Ion and Ioff (on and off current) were obtained from when the device is turned on at high VGS and when the VGS is zero respectively. The table lists the different device parameters obtained from FIGS. 16(a) and (b) for OTFTs made with thermal oxide or a contemplated material as a gate dielectric. The material functions almost equal to that of thermal oxide or better (when annealed at 120° C./30 min) as seen from Table 2 and FIGS. 16(a) and (b).

Thus, specific embodiments, methods of compositions, materials, layers and films for optoelectronic devices, methods of production and uses thereof have been disclosed. It should be apparent, however, to those skilled in the art that many more modifications besides those already described are possible without departing from the inventive concepts herein. The inventive subject matter, therefore, is not to be restricted except in the spirit of the disclosure herein. Moreover, in interpreting the specification and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

1. An optoelectronic device, comprising:
a surface within the device, and
at least one sufficiently light-transmissive crosslinked film, wherein the film is formed from at least one silicon-based material, at least one catalyst, and at least one solvent.

2. The optoelectronic device of claim 1, wherein at least one additional layer is applied to the at least one light-transmissive crosslinked film.

3. The optoelectronic device of claim 1, wherein the device comprises a transistor, a light emitting diode, a color filter, a stainless steel or plastic surface, a photovoltaic cell, a flat panel display, x-ray detectors or a combination thereof.

4. The optoelectronic device of claim 1, wherein the device comprises an active matrix thin film organic light emitting display, a passive matrix organic light emitting display, an active matrix thin film transistor liquid crystal display or a combination thereof.

5. The optoelectronic device of claim 3, wherein the transistor comprises an amorphous silicon thin film transistor, a low temperature polysilicon transistor, an organic transistor, an organic field effect transistor, a static induction transistor, a crystalline silicon transistor or a combination thereof.

6. The optoelectronic device of claim 1, wherein the light-transmissive film forms a passivation layer, a planarization layer or a combination thereof.

7. The optoelectronic device of claim 1, wherein the surface comprises at least one layer.

8. The optoelectronic device of claim 1, wherein the at least one silicon-based compound comprises polyphenylsilsesquioxane, polyphenylsiloxane, phenylsiloxane, phenylsilsesquioxane, methylphenylsilsesquioxane, methylphenylsiloxane or a combination thereof.

9. The optoelectronic device of claim 1, wherein the catalyst comprises a quaternary ammonium salt.

10. The optoelectronic device of claim 9, wherein the quatemary ammonium salt comprises TMAN.

11. The optoelectronic device of claim 1, wherein the crosslinked film comprises at least one adhesion promoter, at least one crosslinking agent, at least one surfactant or a combination thereof.

12. An optoelectronic device, comprising:
a surface within the device, and
at least one sufficiently light-transmissive crosslinkable composition, wherein the composition comprises at least one silicon-based material, at least one crosslinking agent and at least one solvent.

13. The optoelectronic device of claim 12, wherein the device comprises a transistor a light emitting diode, a color filter, a stainless steel or plastic surface, a photovoltaic cell, a flat panel display, x-ray detectors or a combination thereof.

14. The optoelectronic device of claim 13, wherein the transistor comprises an amorphous silicon thin film transistor, a low temperature polysilicon transistor, an organic transistor, an organic field effect transistor, a static induction transistor, a crystalline silicon transistor or a combination thereof.

15. The optoelectronic device of claim 12, wherein the light-transmissive composition forms a film.

16. The optoelectronic device of claim 15, wherein the film is a passivation layer, a planarization layer or a combination thereof.

17. The optoelectronic device of claim 12, wherein the at least one silicon-based compound comprises polyphenylsilsesquioxane, polyphenylsiloxane, phenylsiloxane, phenylsilsesquioxane, methylphenylsilsesquioxane, methylphenylsiloxane or a combination thereof.

18. The optoelectronic device of claim 12, wherein the catalyst comprises a quaternary ammonium salt.

19. The optoelectronic device of claim 18, wherein the quaternary ammonium salt comprises tetramethyl ammonium nitrate.

20. The optoelectronic device of claim 12, wherein the crosslinked composition comprises at least one adhesion promoter, at least one crosslinking agent, at least one surfactant or a combination thereof.

21. An optoelectronic device, comprising:
a surface within the device, and
the composition of claim 12, wherein the composition after a cure having at least one cure temperature and at least one cure time has a weight loss of less than about 2% during further processing at or below cure temperature.

22. The optoelectronic device of claim 21, wherein the weight loss is less than about 1%

23. The optoelectronic device of claim 21, wherein the at least one cure temperature is from about 150° C. to about 400° C. and the at least one cure time is less than about 2 hours.

24. A method of producing an optoelectronic device, comprising:
providing a surface,
providing at least one sufficiently light-transmissive composition, wherein the composition comprises at least one silicon-based material, at least one cayalyst and at least one solvent,
applying the composition to the surface, and
curing the composition to form a sufficiently light-transmissive crosslinked composition.

25. The method of claim 24, wherein the device comprises transistor, a light emitting diode, a color filter, a stainless steel or plastic surface, a photovoltaic cell, a flat panel display, x-ray detectors or a combination thereof.

26. The method of claim 24, wherein the device comprises an active matrix thin film organic light emitting display, a passive matrix organic light emitting display, an active matrix thin film transistor liquid crystal display or a combination thereof.

27. The method of claim 25, wherein the transistor comprises a thin film transistor, an amorphous silicon thin film transistor, a low temperature polysilicon transistor, an organic transistor, an organic field effect transistor, a static induction transistor, a crystalline silicon transistor or a combination thereof.

28. The method of claim 24, wherein the light-transmissive crosslinkable composition forms a passivation layer, a planarization layer or a combination thereof.

29. The method of claim 24, wherein the at least one silicon-based compound comprises polyphenylsilsesquioxane, polyphenylsiloxane, phenylsiloxane, phenylsilsesquioxane, methylphenylsilsesquioxane, methylphenylsiloxane or a combination thereof.

30. The method of claim 24, wherein the at least one catalyst comprises a quaternary ammonium salt.

31. The method of claim 30, wherein the quaternary ammonium salt comprises tetramethyl ammonium nitrate.

32. A method of producing an optoelectronic device, comprising:
providing at least one surface,
the composition of claim 12, wherein the composition after a cure having at least one cure temperature and at least one cure time has a weight loss of less than about 2% during further processing at r below cure temperature,
applying the at least one light-transmissive composition to the at least one surface, and
curing the composition for at least one cure time and for at least one cure temperature.

33. The method of claim 32, wherein the weight loss is less than about 1%.

34. The method of claim 32, wherein the at least one cure temperature is from about 150° C. to about 400° C. and the at least one cure time is less than about 2 hours.

35. A crosslinkable composition, comprising:
polyphenylsilsesquioxane, polyphenylsiloxane, phenylsiloxane, phenylsilsesquioxane, methylphenylsilsesquioxane, methylphenylsiloxane or a combination thereof,
tetramethylammonium nitrate,
at least one solvent, and
an aminopropyl triethoxysilane-based compound.

36. A silicon-based crosslinked film having a percent transmittance for 400 nm to 800 nm of at least about 95% and further comprising at least one of the following properties: a root mean square surface roughness of less than 10 Angstroms, a refractive index greater than or equal to about 1.5, and a field breakdown voltage of at least about 2.5 MV/cm,

37. A transparent silicon-based crosslinked film in the range of 400 nm to 800 nm.

38. A light transmissive silicon-based crosslinked film having a root mean square roughness of less than 10 Angstroms.

39. A light transmissive silicon-based crosslinked film having a field breakdown voltage of at least about 2.5 MV/cm.

40. A light transmissive silicon-based crosslinked film having a refractive index greater than about 1.5.

41. A crosslinkable composition, comprising:
methylphenylsilsesquioxane, methylphenylsiloxane or a combination thereof,
at least one catalyst, and
at least one solvent.

42. The crosslinkable composition of claim 41, wherein the at least one catalyst comprises tetramethylammonium nitrate.
